(19) United States
(12) Patent Application Publication
(10) Pub. No.: US 2010/0162074 A1
(43) Pub. Date: Jun. 24, 2010

(54) APPARATUS AND METHOD FOR CODING QC-LDPC CODE

(75) Inventors: Jong-Ee OH, Daejeon (KR); Minho CHEONG, Daejeon (KR); Yu-Ro LEE, Daejeon (KR); Sok-Kyu LEE, Daejeon (KR); Yongho LEE, Daejeon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics and Telecommunications Research Institute, Daejon (KR)

(21) Appl. No.: 12/642,463

(22) Filed: Dec. 18, 2009

(30) Foreign Application Priority Data
Dec. 19, 2008 (KR) 10-2008-0130462

(51) Int. Cl. H03M 13/05; G06F 11/10

(52) U.S. Cl. 714/752; 714/E11.032

(57) ABSTRACT

A high-speed quasi-cyclic low density parity check (QC-LDPC) coding apparatus for coding inputted information into a generator matrix having a dual diagonal matrix format includes: a parity bit generation unit configured to generate an arbitrary parity bit; a temporary parity bit generation unit configured to constitute the inputted information with circulants, and shift and combine the respective circulants at each row to generate a temporary parity bit; a corrected bit generation unit configured to generate corrected bits of parity bits by using an output of the temporary parity bit generation unit; and a parity bit correction unit configured to correct the temporary parity bit by reflecting an output of the corrected bit generation unit to the output of the temporary parity bit generation unit.

### CROSS-REFERENCE(S) TO RELATED APPLICATIONS

The present application claims priority of Korean Patent Application No. 10-2008-0130462, filed on Dec. 19, 2008, which is incorporated herein by reference in its entirety.

### BACKGROUND OF THE INVENTION

1. Field of the Invention

Exemplary embodiments of the present invention relate to an apparatus and method for coding a low density parity check (LDPC) code; and, more particularly, to a quasi-cyclic LDPC (QC-LDPC) coding apparatus and method.

2. Description of Related Art

As the wired/wireless communication systems are developed toward digital systems, incoming/outgoing data are coded and then transmitted. Diverse coding schemes have been developed. Coding schemes which enable a receiver to correct errors of data transmitted from a transmitter by using forward error correction (FEC) codes are mainly used. Specifically, wireless communication systems further require an FEC coding scheme as a channel coding scheme in a wireless channel environment where data error frequently occurs. Examples of the FEC coding scheme include a convolution coding scheme, a turbo coding scheme, and an LDPC coding scheme. Most attention has been paid to the LDPC coding scheme.

The LDPC coding scheme was introduced by Gallager. The LDPC codes are defined by a parity check matrix in which the minimum number of elements has a value of “1” and most elements have a value of “0”. The LDPC codes are classified into regular LDPC codes and irregular LDPC codes. The regular LDPC codes are LDPC codes suggested by Gallager where all rows in the parity check matrix have the same number of values “1” as elements and all columns have the same number of values “1” as elements. Unlike this, in the parity check matrix of the irregular LDPC codes, there are rows having different numbers of values “1” or columns having different numbers of values “1”. It is known that the irregular LDPC codes are superior to the regular LDPC codes in an error correction performance.

It is assumed that the LDPC code is coded in accordance with a systematic method. That is, a part of a packet is outputted in the same format as inputted bit, and a rest part of the packet has a format that additional information corresponding to a parity bit is consecutively added and outputted. Therefore, the coding operation is performed when the input signal is completely inputted to a block which manages a coding function. Furthermore, a rate of the parity bit in the entire packet is different according to a code rate. Therefore, the code rate is fixed by an H matrix. The coding procedure will be described below with reference to FIG. 1, taking an LDPC code as an example.

FIG. 1 is a block diagram explaining the concept of an LDPC coding method.

An LDPC code is a linear block code, and a basic coding is performed by the product of a generator matrix and information vector. That is, in FIG. 1, a codeword 100 outputted after an LDPC coding is expressed as the matrix product of information 110 to be transmitted and a generator matrix 120. Also, the generator matrix 120 includes a parity matrix 122. Moreover, in the LDPC code, the product of the codeword 100 and the parity matrix 122 of the generator matrix 120 has a zero matrix.

Therefore, a correlated generator matrix may be calculated using a parity check matrix. However, when the coding of the LDPC code is performed, such a method is not performed due to complexity. This is because the parity check matrix 122 has a sparse format, which is one of features of the LDPC code. If the generator matrix 120 is calculated using the parity check matrix 122 having the above-described format, it can be seen that many elements of the generator matrix 120 have “1”. That there are a large number of “1s” means that the operations must be performed many times with information vector elements during the coding. This means the increase of hardware complexity for the processing. On the contrary, if there are a large number of “0s”, a complexity problem does not occur because it is unnecessary to consider information vector element of a corresponding position. Thus, if the coding of the LDPC code is performed like a linear block code, the coding may be performed based on the parity check matrix 122, without using the generator matrix 120, when performing the coding in order to solve the complexity problem to some extent.

The generator matrix 120 may be divided into a systematic or non-systematic generator matrix according to its format. In the case of the systematic generator matrix, a predetermined portion of the codeword, which is obtained by the product of the information vector and the generator matrix, is made equal to the information vector. That is, the information vector appears in the codeword as it is. On the contrary, in the case of the non-systematic generator matrix, the information vector does not appear in the codeword. The information vector may be made to appear in a predetermined portion of the codeword by inserting an identity matrix into a specific portion of the systematic generator matrix. This may be expressed as Equation 1 below.

$$\begin{matrix}\begin{matrix}U = m G = m [ P \vert {I}_{k} ] & Eq . 1\end{matrix} \\ \begin{matrix}U = [ \begin{matrix}{u}_{1} & {u}_{2} & {u}_{3} & … & {u}_{n}\end{matrix} ] \\ = [ \begin{matrix}{m}_{1} & {m}_{2} & {m}_{3} & … & {m}_{k}\end{matrix} ] \times \begin{matrix}[ \begin{matrix}{g}_{1 , k + 1} & … & {g}_{1 , n} \\ {g}_{2 , k + 1} & … & {g}_{2 , n} \\ {g}_{3 , k + 1} & … & {g}_{3 , n} \\ ⋮ & ⋱ & ⋮ \\ {g}_{k , k + 1} & … & {g}_{k , n}\end{matrix} \\ ⏟ \\ P\end{matrix} \begin{matrix}\begin{matrix}1 & 0 & 0 & … & 0 \\ 0 & 1 & 0 & … & 0 \\ 0 & 0 & 1 & … & 0 \\ ⋮ & ⋮ & ⋮ & ⋱ & ⋮ \\ 0 & 0 & 0 & … & 1\end{matrix} ] \\ ⏟ \\ {I}_{k}\end{matrix}\end{matrix}\end{matrix}$$

The codeword U is calculated by the product of the information vector m and the generator matrix G. A predetermined portion of the systematic generator matrix is constituted with a submatrix P (which is not limited to formats, any matrix is possible), and a remaining portion thereof is constituted with an identity matrix which is a square matrix having the same size as the information vector. If the identity matrix is placed behind, the information vector appears at a tail portion of the codeword, and a head portion of the codeword becomes the parity bit. If the positions of the submatrix P and the identity matrix are exchanged with each other, the information vector appears at a head portion, and a tail portion of the codeword becomes the parity bit.

In the case of using the parity check matrix, the parity check matrix may be mostly easily generated using a Gaussian elimination method. In the Gaussian elimination method, there is an unknown value, and the parity check matrix is generated using a method of solving the known value using an equation. However, in the case of using the Gaussian elimination method, a large number of equations must be calculated during the elimination, causing increase of complexity. A Richardson coding method is used as an LDPC coding method for solving the above-described problem.

The Richardson coding method divides the parity check matrix with the LDPC code into blocks, and generates parity bits through correlated matrix equations. Specifically, the H matrix is divided into six submatrices and an output parity bit is produced when an input vector is given as a simultaneous equation of the matrices. The Richardson coding method may code the elements of the matrix, without regard to values of the elements, only if the matrix has an approximate lower triangular form. That is, the Richardson coding method has a limitation in that it can use only in an arbitrary parity check matrix having an approximate lower triangular form.

Next, a QC-LDPC coding method suggested by Fossorier will be described below.

The QC-LDPC coding method uses a quasi-cyclic matrix. First, a cyclic matrix will be described. As illustrated in FIG. 2, the cyclic matrix has an N×N square matrix in which “1” exists in each column, and “1” can be shifted by 1 bit. FIG. 2 illustrates an example when an N×N square matrix is constituted with a cyclic matrix.

An A⁰ matrix 210 is a 4×4 square matrix which is a unit matrix having is at diagonal elements. An A¹ matrix 220 is a square matrix in which positions of is in the A⁰ matrix 210 are shifted right by 1 bit. An A² matrix 230 is a square matrix in which positions of is in the A¹ matrix 220 are again shifted right by 1 bit. An A³ matrix 240 is a square matrix in which positions of is in the A² matrix 230 are again shifted right by 1 bit. An A⁻ matrix 200 is a zero matrix in which all elements of the 4×4 square matrix are “0”.

The QC-LDPC coding method suggested by Fossorier is a QC LDPC code showing the elements of the parity check matrix as a cyclic shifted identity matrix and “0” matrix, as not the elements “0” and “1” on GF(2). The LDPC code adopted in the Institute of Electrical and Electronics Engineers (IEEE) 802.16e or 802.11n is an irregular QC-LDPC code, and a parity bit part thereof has a block-type dual diagonal matrix format.

FIG. 3 illustrates a configuration of a parity check matrix having a dual diagonal matrix format for a QC-LDPC coding and its relationship with a codeword.

As described above, a codeword 330 becomes a zero matrix 340 when it is multiplied by two parity check matrices 310 and 320. The latter 320 of the two parity check matrices 310 and 320 has a dual diagonal matrix format. Since the QC-LDPC coding is performed using such a structure, the complexity in the practical implementation increases.

Another method was suggested by Zongwang Li et al. According to this method, the matrix product operation of a generator matrix obtained using a parity check matrix of a QC-LDPC code and information bits is divided into two steps, and parity bits are generated at each step through a coder implemented with a cyclic shift-register. However, the use of the cyclic shift-register increases a waiting time.

### SUMMARY OF THE INVENTION

An embodiment of the present invention is directed to a QC-LDPC coding apparatus and method, which are capable of reducing complexity.

Another embodiment of the present invention is directed to a QC-LDPC coding apparatus and method, which are capable of reducing a waiting time during coding.

Another embodiment of the present invention is directed to a QC-LDPC coding apparatus and method, which are capable of reducing complexity and waiting time by using a parity check matrix using a QC-LDPC scheme proposed in the IEEE 802.1x standard.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

In accordance with an embodiment of the present invention, a high-speed quasi-cyclic low density parity check (QC-LDPC) coding apparatus for coding inputted information into a generator matrix having a dual diagonal matrix format includes: a parity bit generation unit configured to generate an arbitrary parity bit; a temporary parity bit generation unit configured to constitute the inputted information with circulants, and shift and combine the respective circulants at each row to generate a temporary parity bit; a corrected bit generation unit configured to generate corrected bits of parity bits by using an output of the temporary parity bit generation unit; and a parity bit correction unit configured to correct the temporary parity bit by reflecting an output of the corrected bit generation unit to the output of the temporary parity bit generation unit.

In accordance with another embodiment of the present invention, a high-speed quasi-cyclic low density parity check (QC-LDPC) coding method for coding inputted information into a generator matrix having a dual diagonal matrix format includes: generating an arbitrary parity bit; constituting the inputted information with circulants, and shifting and combining the respective circulants at each row to generate a temporary parity bit; generating corrected bits of parity bits by using an output of the temporary parity bit generation unit; and correcting the temporary parity bit by reflecting an output of the corrected bit generation unit to the output of the temporary parity bit generation unit.

### BRIEF DESCRIPTION OF THE DRAWINGS

FIG. 1 is a block diagram explaining the concept of an LDPC coding method.

FIG. 2 illustrates an example when an N×N square matrix is constituted with a cyclic matrix.

FIG. 3 illustrates a configuration of a parity check matrix having a dual diagonal matrix format for a QC-LDPC coding and its relationship with a codeword.

FIG. 4 is a block diagram illustrating the configuration of a QC-LDPC coding apparatus in accordance with an embodiment of the present invention.

FIG. 5 illustrates the internal configuration of the temporary parity bit generation unit in the QC-LDPC coding apparatus in accordance with the embodiment of the present invention.

FIG. 6 is a timing diagram of the respective subblocks according to clocks in the QC-LDPC coding apparatus in accordance with the embodiment of the present invention.

FIG. 7 is a block diagram illustrating the exemplary implementation of P(H) using the coding apparatus in accordance with an embodiment of the present invention.

FIG. 8 is a block diagram of a coding apparatus which is extended from the coding apparatus using the circulant matrix of the parity check matrix of FIG. 7.

FIG. 9 is a block diagram of the coding apparatus using H in which the coding apparatus using P(H) of FIG. 4 is extended.

FIG. 10 illustrates the values inputted from the QC-LDPC coding apparatus in accordance with the embodiment of the present invention, based on the consecutive clocks.

FIG. 11 illustrates the parity check matrix having a codeword length of 1944 and a rode rate ½ proposed in the IEEE 802.11n draft.

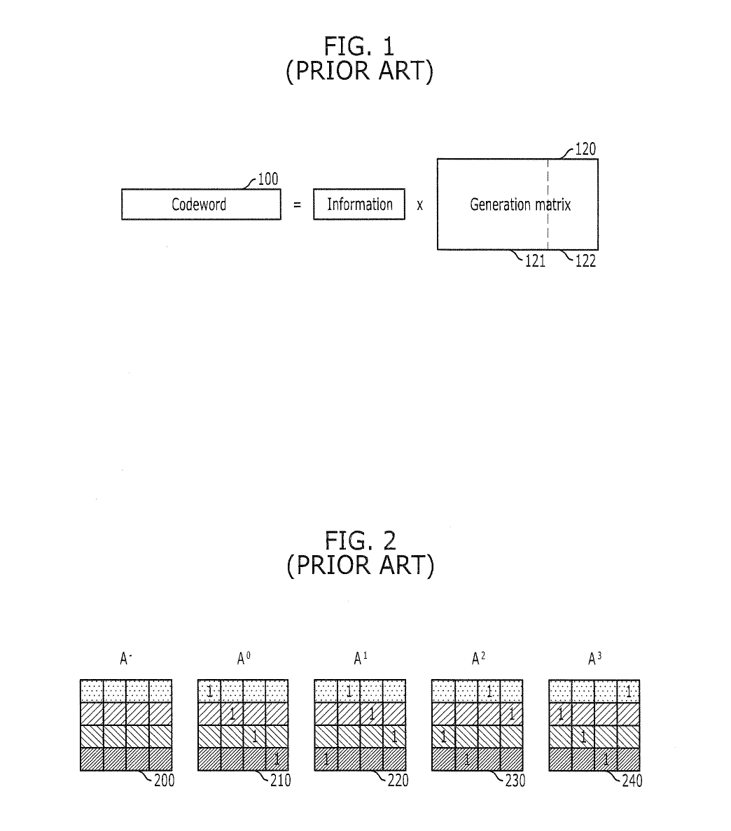

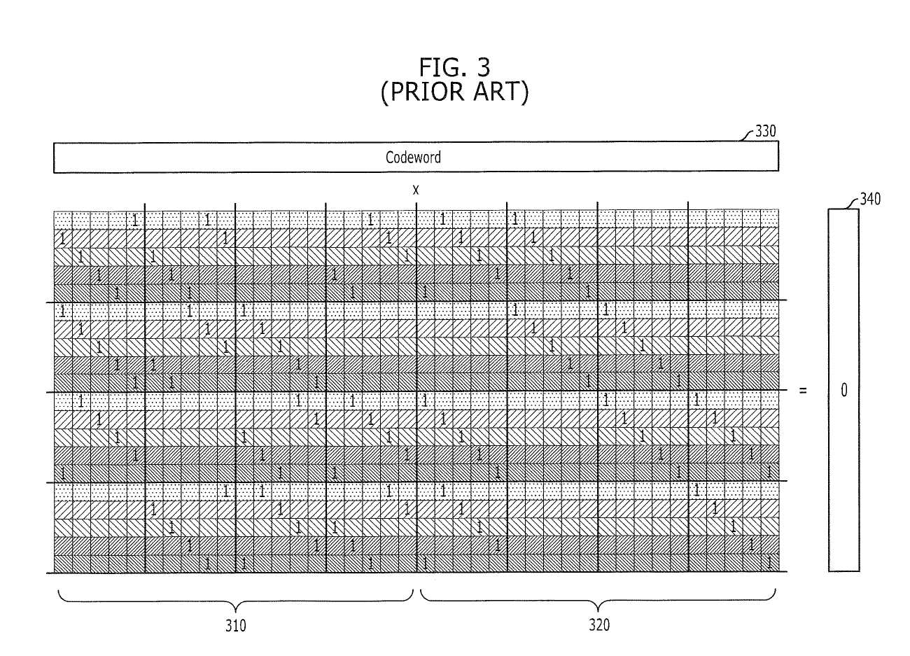

### DESCRIPTION OF SPECIFIC EMBODIMENTS

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

A QC-LDPC coding method in accordance with the exemplary embodiment of the present invention will be described below based on an LDPC coding method. Instead of an arbitrary parity check matrix of an LDPC code, a parity check matrix proposed in the IEEE 802.1x standard will be used. Therefore, an efficient LDPC coding having a low linear complexity can be performed in a unique method differentiated from an existing coding method. To this end, the LDPC coding method in accordance with an exemplary embodiment of the present invention can have a low linear complexity by using directly using a proposed parity check matrix in a coding operation. Furthermore, an arbitrary parity bit generation, a corrected bit generation, and a parity bit correction are sequentially performed by using a circulant matrix of the proposed parity check matrix and a parity check matrix having a dual diagonal parity format.

Thus, the QC-LDPC coding method achieves an entire coding through a consecutive partial coding by applying a quasi-cyclic characteristic.

Furthermore, in the parity check matrix in accordance with the exemplary embodiment of the present invention, the matrix product operation of information vector and systematic part of the parity check matrix is implemented through a small number of global wires and a cyclic shift-register. Thus, the efficient LDPC coding apparatus having a low linear complexity by using the parity check matrix proposed in the standard can maintain the number of global wires required when the coding is performed by extending an LDPC coding method using the circulant matrix of the proposed parity check matrix.

In the exemplary embodiment of the present invention, the efficient LDPC coding step having a lower linear complexity by using the parity check matrix proposed in the standard uses a parity check matrix having the proposed dual diagonal parity format. Thus, the QC-LDPC coding method in accordance with the exemplary embodiment of the present invention may be implemented with parallel shift-registers in order to performing the entire coding by consecutively executing the partial coding by applying the coding method, which is sequentially performed through the arbitrary parity bit generation, the corrected bit generation, and the parity bit correction, to the quasi-cyclic characteristic of the parity check matrix. Moreover, there are disclosed an apparatus and method which can reduce necessary clocks by minimizing idle-state shift-registers when the consecutive coding of various information vectors is performed.

First, the expression of the QC-LDPC code and the parity check matrix H proposed in the IEEE 802.11n and 802.16e standards will be described. The term “circulant” defines a square matrix in which the respective rows have the same weight and are arranged cyclically from the uppermost row to the lowermost row, as described in the background of the invention. Furthermore, the first row of the circulant is defined as a circulant generator. The circulant can be completely generated through a generator and represented as a generator. As one example, the circulant having “1” as the weight of each row can be defined. In the matrix A=(A_{i, j}), A_{i, j} is expressed as Equation 2 below, and the matrix A is defined as a B×B permutation matrix.

$${A}_{i , j} = \{ \begin{matrix}1 & \text{if} i {⊕}_{B} 1 = j \\ 0 & \text{otherwise}\end{matrix} \qquad Eq . 2$$

where a a ⊕_{B} b≡(a+b) mod B

The matrix Aⁱ is defined as a circulant permutation matrix obtained by shifting right the B×B unit matrix by i (where i is an integer from 0 to B−1). The B×B zero matrix is defined as A⁻, as described above with reference to FIG. 3. Therefore, i has a sample space of {−, 0, 1, . . . , B−1}, and Aⁱ has a sample space of {A⁻, A⁰, . . . , A^{B-1}}. When assuming that u is information sequence having {u₀, u₁, . . . , uₖ₋₁}, uᵢ is defined as information vector having a format of {u_{i, 0}, u_{i, 1}, . . . , u_{i, B-1}} for i (where, i is an integer from 0 to K−1). Also, u is coded into a codeword c having a format of cₛ|cₚ. cₛ has a format of {u₀, u₁, . . . , u_{K-1}} and is defined as a 1×(KB) vector corresponding to a systematic part of c. When cₚ is expressed as {p₀, p₁, . . . , p_{M-1}}, pᵢ has a format of {p_{i, 0}, p_{i, 1}, . . . , p_{B-1}} for i (where, i is an integer from 0 to M−1) and is defined as a 1×(MB) vector corresponding to a parity part of c. All u_{i, j} and p_{i, j} are defined in GF(2). ⊕ is defined as an addition defined in GF(2). H is an (MB)×(NB) matrix and is defined as Equation 3 below.

$$H = [ {H}_{s} \vert {H}_{p} ] = [ \begin{matrix}{A}^{{s}_{0 , 0}} & {A}^{{s}_{0 , 1}} & … & {A}^{{s}_{0 , N - 1}} \\ {A}^{{s}_{1 , 0}} & {A}^{{s}_{1 , 1}} & … & {A}^{{s}_{1 , N - 1}} \\ ⋮ & ⋮ & ⋱ & ⋮ \\ {A}^{{s}_{M - 1 , 0}} & {A}^{{s}_{M - 1 , 1}} & … & {A}^{{s}_{M - 1 , N - 1}}\end{matrix} ] \qquad Eq . 3$$

In Equation 3 above, all s_{i, j} are defined in the sample space of {−, 0, 1, . . . , B−1}. As such, the LDPC code coded using the matrix H constituted with the circulant permutation matrices is defined as a QC-LDPC code. In addition, in Equation 3 above, Hₛ is defined as an (MB)×(KB) matrix related to the systematic part of c, and Hₚ is defined as an (MB)×(MB) matrix related to the parity part of c. P(H) is defined as a circulant matrix of H in which the zero matrix and the circulant permutation matrix of H are represented by 0 and 1. E(H) is defined as an exponential matrix of H. In this case, E(H₅) and E(Hₚ) are defined like E(H). Thus, E(H), E(Hₛ), and E(Hₚ) may be defined as Equation 4 below.

$$\begin{matrix}E ( H ) = [ \begin{matrix}{s}_{0 , 0} & {s}_{0 , 1} & … & {s}_{0 , N - 1} \\ {s}_{1 , 0} & {s}_{1 , 1} & … & {s}_{1 , N - 1} \\ ⋮ & ⋮ & ⋱ & ⋮ \\ {s}_{M - 1 , 0} & {s}_{M - 1 , 1} & … & {s}_{M - 1 , N - 1}\end{matrix} ] , & Eq . 4 \\ E ( {H}_{s} ) = [ \begin{matrix}{s}_{0 , 0} & {s}_{0 , 1} & … & {s}_{0 , K - 1} \\ {s}_{1 , 0} & {s}_{1 , 1} & … & {s}_{1 , K - 1} \\ ⋮ & ⋮ & ⋱ & ⋮ \\ {s}_{M - 1 , 0} & {s}_{M - 1 , 1} & … & {s}_{M - 1 , K - 1}\end{matrix} ] , & \\ E ( {H}_{p} ) = [ \begin{matrix}{s}_{0 , K} & {s}_{0 , K + 1} & … & {s}_{0 , N - 1} \\ {s}_{1 , K} & {s}_{1 , K + 1} & … & {s}_{1 , N - 1} \\ ⋮ & ⋮ & ⋱ & ⋮ \\ {s}_{M - 1 , K} & {s}_{M - 1 , K + 1} & … & {s}_{M - 1 , N - 1}\end{matrix} ] & \end{matrix}$$

The matrix H proposed in the IEEE 802.11n standard and IEEE 802.16e standard is constituted in the form of the circulant permutation format and has the dual diagonal parity format. The dual diagonal parity format is defined as Equation 5 below.

$$\begin{matrix}{s}_{0 , K} = {s}_{M - 1 , K} , {s}_{\frac{M}{2} , K} = 0 , {s}_{i , K + i + 1} = 0 \text{for} 0 \leq i < M - 1 , & Eq . 5 \\ {s}_{i , K + 1} = 0 \text{for} 1 \leq i < M , {s}_{ij} = - \text{elsewhere} & \end{matrix}$$

One example is taken based on the definition of Equation 5. When M=6, E(H_{P}) may be expressed as Equation 6 below.

$$E ( {H}_{p} ) = [ \begin{matrix}{s}_{0 , 6} & 0 & - & - & - & - \\ - & 0 & 0 & - & - & - \\ - & - & 0 & 0 & - & - \\ 0 & - & - & 0 & 0 & - \\ - & - & - & - & 0 & 0 \\ {s}_{5 , 6} & - & - & - & - & 0\end{matrix} ] \qquad Eq . 6$$

The coding method using the matrix H proposed like Equation 6 is derived from the coding method using P(H) of the proposed matrix H. If the extension from the coding using P(H) to the coding using H is considered when performing the coding of the QC-LDPC code, a new efficient coding apparatus and method may be implemented by applying the quasi-cyclic characteristic of H. The coding in accordance with the exemplary embodiment of the present invention is performed by three blocks.

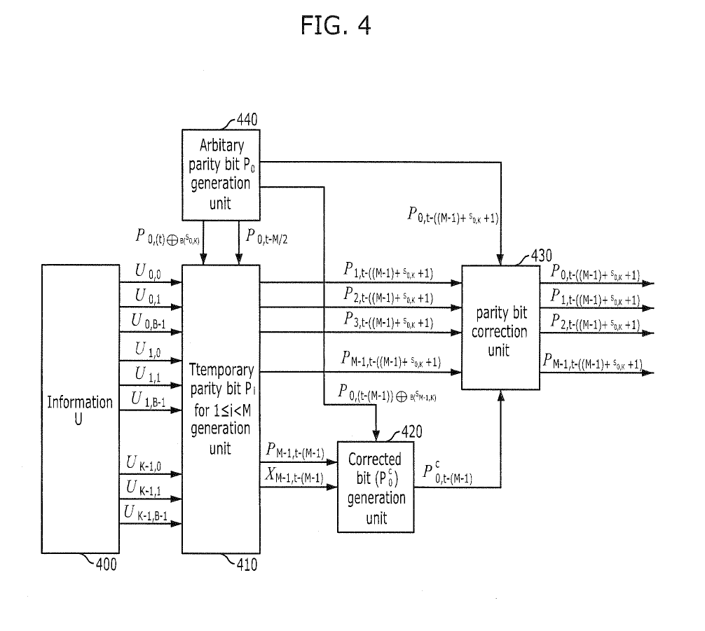

FIG. 4 is a block diagram illustrating the configuration of a QC-LDPC coding apparatus in accordance with an embodiment of the present invention. The configuration of the QC-LDPC coding apparatus will be described with reference to FIG. 4.

As described above, it is assumed that information u 400 is information sequence having {u₀, u₁, . . . , u_{K-1}} and uᵢ has a format of {u_{i, 0}, u_{i, 1}, . . . , u_{i, B-1}} for i (where, i is an integer from 0 to K−1). Thus, as illustrated in FIG. 4, the information u is inputted in parallel. When the information u is inputted, a temporary parity bit generation unit 410 generates temporary parity bits by using parity bits received from an arbitrary parity bit generation unit 440. The arbitrary parity bit generation unit 440 generates arbitrary parity bits, based on a predefined criterion, and provides the arbitrary parity bits to the temporary parity bit generation unit 410, a corrected bit generation unit 420, and a parity bit correction unit 430 In addition, the predefined criterion may be information on the parity bits to be generated. The temporary parity bit generation unit 410 generates codewords with respect to the parity bits by using the inputted information u 400 and the parity bits provided from the arbitrary parity bit generation unit 440, and transfers the generated codewords to the parity correction unit 430 and the corrected bit generation unit 420. The corrected bit generation unit 420 generates parity bits to be corrected by using some of the generated codewords, and transfers the generated parity bits to the parity bit correction unit 430. The parity bit correction unit 430 corrects the codewords generated by the temporary parity bit generation unit 410, based on the parity bits generated from the corrected bit generation unit 420, and outputs the correction result.

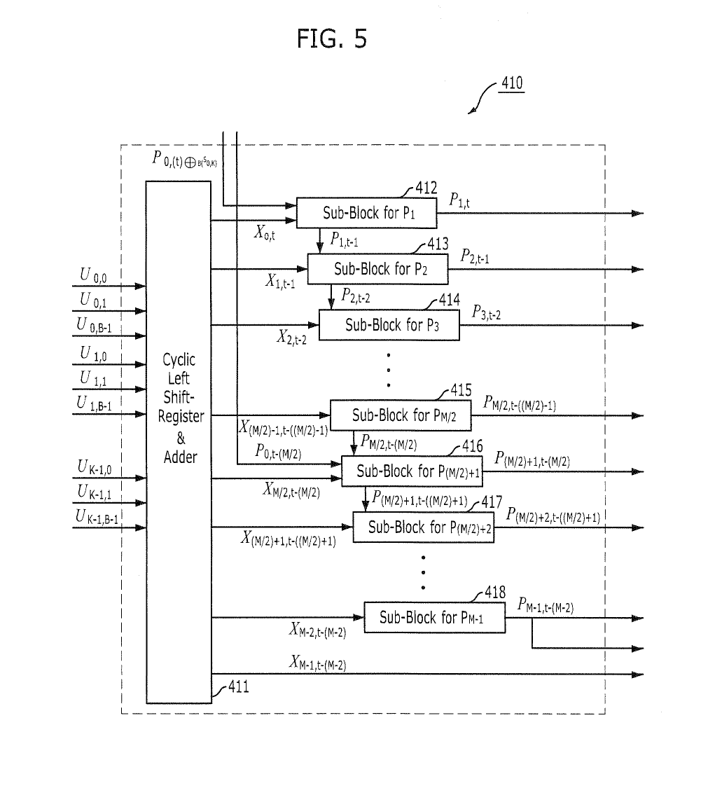

FIG. 5 illustrates the internal configuration of the temporary parity bit generation unit in the QC-LDPC coding apparatus in accordance with the embodiment of the present invention. The operations of the respective operations will be described below, based on clocks, and t represents a lock index.

The temporary parity bit (pᵢ) generation unit 410 may be roughly divided into two parts: a cyclic left shift-register and adder 411, and subblocks for generating the parity bits. The first subblock 412 among the subblocks 412 to 418 for generating the parity bits receives the parity bit provided to the arbitrary parity bit generation unit 440, and the remaining subblocks 413 to 418 receive the parity bit information from each previous subblock. That is, the subblock 412 for P₁ may be configured to receive the parity bit information provided from the arbitrary parity bit generation unit 440, and calculate an equation for the first row of the parity check matrix. The calculated value of the equation for the first row is used in an equation for the second row of the parity matrix. That is, the equation for the second row may be solved using the calculated solution of the equation for the first row. In this way, each equation is solved. The last subblock 418 calculates the (M−1)th row of the parity check matrix and outputs the calculated value.

The operation of the QC-LDPC coding apparatus having the above-described configuration will be described with respect to time t. The subblocks 412 to 418 include sequential subblocks for pᵢ (where i is an integer from 1 to M−1). The respective subblocks illustrated in FIG. 5, based on clocks, may be expressed as Equation 7.

$$\begin{matrix}\text{Cyclic Left Shift-Register \& Adder} \{ 0 \leq t < B \} \text{:} & Eq . 7 \\ {x}_{i , t} = {\sum }_{j = 0}^{K - 1} {{a}_{i , j} ( {u}_{j}^{t} )}^{T} \text{for} 0 \leq i < M & \\ \text{Subblock for} {p}_{1} \{ 0 \leq t < B \} \text{:} & \\ {p}_{1 , t} = {p}_{0 , ( t ) {⊕}_{B} ( {s}_{0 , K} )} ⊕ {x}_{0 , t} & \\ \text{Subblock for} {p}_{i} ( 2 \leq i < M \text{except for} i = \frac{M}{2} + 1 ) \\ \{ ( i - 1 ) \leq t < ( i - 1 ) + B \} \text{:} & \\ {p}_{i , t - ( i - 1 )} = {p}_{i - 1 , t - ( i - 1 )} ⊕ {x}_{i - 1 , t - ( i - 1 )} & \\ \text{Subblock for} {p}_{\frac{M}{2} + 1} \{ \frac{M}{2} \leq t < \frac{M}{2} + B \} & \\ {p}_{\frac{M}{2} + 1 , t - \frac{M}{2}} = {p}_{\frac{M}{2} , t - \frac{M}{2}} ⊕ {p}_{0 , t - \frac{M}{2}} ⊕ {x}_{\frac{M}{2} , t - \frac{M}{2}} & \end{matrix}$$

In Equation 7 above, a_{i, j} defined as an A^{S} generator, uⱼ^{t} defines the cyclic left t-shifted vector, and a superscript T defines a transposition operation of a vector.

The operation of the configuration illustrated in FIG. 5 will be again described below, based on the contents defined in Equation 7 above. Before starting the coding, the information u is previously transferred to the cyclic left shift-registers. Although the cyclic left shift-registers are not illustrated in FIG. 5, they are connected to M adders through global wires.

Since the coding apparatus using H is extended from the coding apparatus using P(H), the number of global wires required is not increased but maintained as it is. Although extending from P(H) to H, the complexity in this processing part is not increased. In order to perform the coding based on the dual diagonal parity format, the arbitrary parity bit generation block generates the parity bit p₀ arbitrarily. In order for a simple operation, the arbitrary parity bit p₀ may be set to a 1×B zero vector. During consecutive (M−2)+B clocks, the temporary parity bit generation block partially generates different temporary parity bits pᵢ derived from the arbitrary parity bit pₒ for (where is an integer from 1 to M−1) at each clock. When the clock is (M−2)+(B−1), the different temporary parity bits pᵢ for i (where i is an integer from 1 to M−1) are completely generated.

The corrected bit generation unit 420 based on the clocks of FIG. 4 may be expressed as Equation 8 below. Generation of corrected bit (p₀^{c}){(M−1)≦t<(M−1)+B}:

p_{0,t-(M-1)}^{c}=p_{0,(t-(M-1))⊕}_{₈}₍ₛ_{_{M-1,K)}}⊕p_{M-1,t-(M-1)}⊕x_{M-1,t-(m-1)} Eq. 8

Next, the operation of the corrected bit generation unit 420 of FIG. 4 will be described.

p₀^{c} is a corrected bit for the arbitrary parity bit p₀. During consecutive B clocks, p₀^{c} is partially generated at each clock. When the clock is (M−1)+(B−1), p₀^{c} is completely generated.

The parity bit correction unit 430 based on the clocks of FIG. 4 may be again expressed as Equation 9 below.

$$\begin{matrix}\text{Parity bit correction} \\ \{ ( M - 1 ) + {s}_{0 , K} + 1 \leq t < ( M - 1 ) + {s}_{0 , K} + 1 + B \} \text{:} & Eq . 9 \\ \text{for} i = 0 , & \\ {p}_{i , t - ( ( M - 1 ) + {s}_{0 , K} + 1 )} = {p}_{i , t - ( ( M - 1 ) + {s}_{0 , K} + 1} ⊕ {p}_{1 , t - ( ( M - 1 ) + {s}_{0 , K} + 1 )}^{c} & \\ \text{for} 1 \leq i < \frac{M}{2} + 1 , & \\ {p}_{i , t - ( ( M - 1 ) + {s}_{0 , K} + 1 )} = {p}_{i , t - ( ( M - 1 ) + {s}_{0 , K} + 1 )} ⊕ {p}_{0 , ( t - ( ( M - 1 ) + {s}_{0 , K} + 1 ) ) {⊕}_{B} ( {s}_{s , K} )}^{c} & \\ \text{for} \frac{M}{2} + 1 \leq i < M , & \\ {p}_{i , t - ( ( M - 1 ) + {s}_{0 , K} + 1 )} = {p}_{i , t - ( ( M - 1 ) + {s}_{0 , K} + 1 )} ⊕ {p}_{0 , ( t - ( ( M - 1 ) + {s}_{0 , K} + 1 ) ) {⊕}_{B} ( {s}_{s , K} )}^{c} ⊕ {p}_{0 , t - ( ( M - 1 ) + {s}_{0 , K} + 1 )}^{c} & \end{matrix}$$

The operation of the parity bit correction unit 430 will be described below, based on Equation 9 above. During consecutive B clocks, the arbitrary parity bit p₀ and the different temporary parity bits pᵢ for i (where i is an integer from 1 to M−1) are partially corrected at each clock. As a result, the coding method in accordance with the embodiment of the present invention consecutively performs the M-parallel partial coding. When the clocks necessary to input the information u 400 to the temporary parity bit generation unit 410 is neglected, M+s_{0, K}+B clocks are required for the coding of KB information bits. However, when the n number of information u is consecutively coded, the coding method in accordance with the embodiment of the present invention requires (M+s_{0, K}+B)+(n−1)×(s_{0, k}+B), which is less than n×(M+s_{0, K}+B).

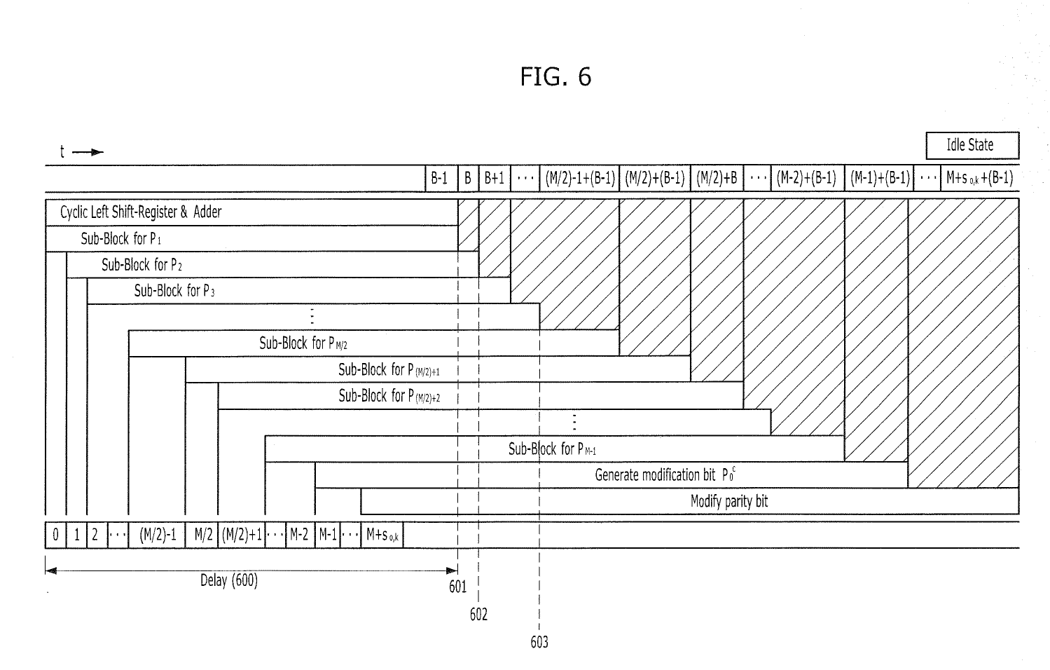

A detailed description will be made with reference to FIG. 6. FIG. 6 is a timing diagram of the respective subblocks according to clocks in the QC-LDPC coding apparatus in accordance with the embodiment of the present invention. A hatched region in FIG. 6 represents a state in which each subblock normally operates to output signals, and a delay time of each subblock is also illustrated. That is, the cyclic left shift-register and adder 411 starts to output the signals normally at the time point of the clock B. That is, the reference numeral 600 represents the time point from the input of the information bit to the signal output of the cyclic left shift-register and adder 400 with the use of the inputted information bit. The initial output is performed at the time point 601, and the normal output is achieved at the subblock 412 for P₁. The normal output is also achieved at the subblock 413 for P₂ from the time point 602 when the B+1 clock starts. The normal output is also achieved at the subblock 414 for P₃ from the time point 603. As illustrated in FIG. 5, when the respective subblocks receive signals from their previous subblock, the next subblocks output the normal signals. Thus, in order for all the subblocks to output signals, the delay time is required as many subblocks from the time point when the clock B is inputted.

Therefore, as illustrated in FIG. 6, when the information u 400 is coded using the coding method in accordance with the embodiment of the present invention, there exist idle-state subblocks and blocks after the clock B−1.

In the consecutive coding, the idle-state subblocks and blocks are used for the coding of next information. Thus, clocks required for the entire coding may be reduced. The reduction of the clocks depends on the circulant size B and s_{0, K} of E(H).

In the case of the conventional two-step coding method, the coding of the next information cannot be performed until the coding of the information u is completed. That is, when the consecutive coding is performed on the n number of information u, the two-step coding method requires n×(M+s_{0, K}+B), which is larger than the coding method in accordance with the embodiment of the present invention.

In view of the use of the cyclic left shift-register, the operation of the cyclic left shift-register and adder subblock 411 is similar to the operation of the first step of the two-step coding method. However, the cyclic left shift-register used in the embodiment of the present invention is induced by the extension from the coding apparatus using P(H) to the coding apparatus using H. Also, the cyclic left shift-register in accordance with the embodiment of the present invention, which is used in the two-step coding method, is induced during the procedure of performing the coding by applying the matrix decomposition to the generator matrix G obtained through H. Therefore, the number of global wires connected to the cyclic left shift-register in the coding method in accordance with the embodiment of the present invention is identical to the number of global wires connected to the cyclic left shift-register in the first step of the two-step coding method.

However, due to the inverse matrix operation of Hₚ in the second step of the two-step coding method, the cyclic left shift-register of the second step additionally requires more global wires than that of the first step.

For the understanding of the invention, E(H) and E(Gₚ) of E(H) will be described below, taking the following example. The matrix Gₚ is defined as a matrix corresponding to the parity part of the systematic G. E(Gₚ) is defined as exponentials of the circulant, which are the sum of the circulant permutation matrices. As one example, the circulant having an exponential of 0⋄1⋄4 is defined as the sum of the circulant permutation matrices A⁰, A¹ and A⁴, and may be expressed as Equation 10 below.

$$\begin{matrix}E ( H ) = [ \begin{matrix}4 & 3 & - & 2 \\ 0 & 2 & 0 & - \\ 1 & - & 3 & 1 \\ - & 4 & 1 & 3\end{matrix} \vert \begin{matrix}1 & 0 & - & - \\ - & 0 & 0 & - \\ 0 & - & 0 & 0 \\ 1 & - & - & 0\end{matrix} ] & Eq . 10 \\ E ( {G}_{p} ) = [ \begin{matrix}0 ◇1◇4 & 0 ◇1◇3◇4 & 1 ◇3◇4 & 0 ◇3◇4 \\ 1 ◇2◇3 & 0 ◇1 & 0 ◇1◇3 & 0 ◇2 \\ 0 ◇2◇4 & 1 ◇3◇4 & 0 ◇1◇3◇4 & 1 ◇3 \\ 2 ◇3◇4 & 1 ◇2 & 1 ◇2 & 1 ◇3\end{matrix} ] & \end{matrix}$$

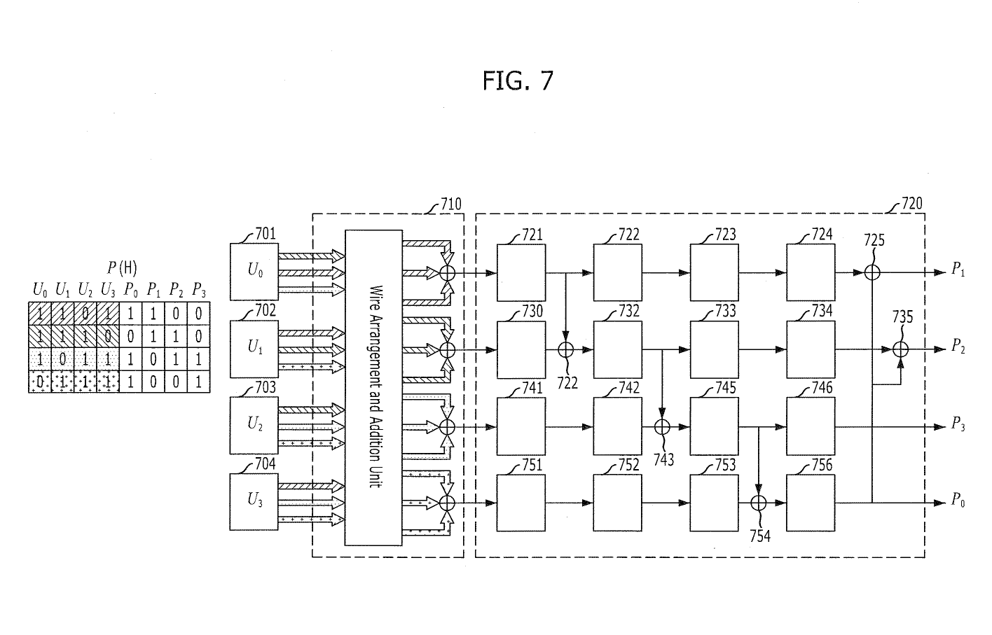

If P(H) like the example of Equation 10 above is implemented by the coding method in accordance with the embodiment of the present invention, it may be illustrated like FIG. 7.

FIG. 7 is a block diagram illustrating the exemplary implementation of P(H) using the coding apparatus in accordance with an embodiment of the present invention.

Referring to FIG. 7, when i in the information u is 0, 1, 2, and 3, the respective output units 701, 702, 703 and 704 for the zeroth-row information u₀, the first-row information u₁, the second-row information u₂, and the third-row information u₃ use three different global wires. A wire arrangement and addition unit 710 arranges global wires of the output units 701, 702, 703 and 704 and adds the arranged global wires. The wire arrangement and addition unit 710 outputs the global wire arrangement and addition result corresponding to the respective parities. The parties are provided to a parity generation unit 720 for generating the parity matrices. The parity generation unit 720 includes shift-registers 721, 722, 723, 724, 730, . . . , 756 and adders 725, 731, 743 and 754.

The shift-registers 721, 722, 723 and 724 sequentially shift the added input value to output p₁. The output of the first shift-register 721 among the shift-registers 721, 722, 723 and 724 which output p₁ influences the output of p₂. The previous shift-register influences the output of the next shift-register. In addition, the second shift-register 732 among the shift-registers 730, 732, 733 and 734 which output p₂ influences the input of the third shift-register 745 among the shift-registers 741, 742, 745 and 746 which output p₃. In this way, the respective shift-registers are influenced and the final value is fed back to P₁ and P₂ and corrected.

That is, the following rule is applied on the rows other than the first row. It is assumed that the previous row number, that is, the first row number, is 1; the second row number is 2; and the third row number is 3. In the second row, the output of the shift register having the previous row number among the shift-registers of the previous row, that is, the output of the first shift-register, is added before being inputted to the shift-register having its own row number, that is, the second shift-register.

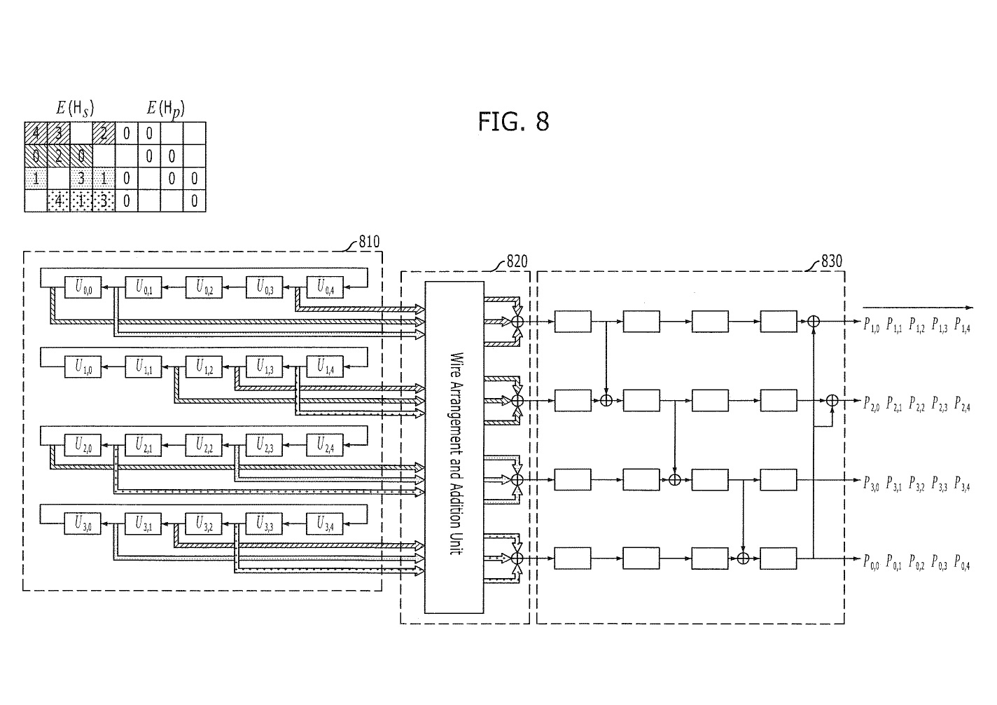

The case of extending the configuration of FIG. 7 will be described below. FIG. 8 is a block diagram of a coding apparatus which is extended from the coding apparatus using the circulant matrix of the parity check matrix of FIG. 7.

Specifically, FIG. 8 is a block diagram of the coding apparatus using H in which P(H) of FIG. 7 is extended and s_{0, K} and s_{M-1, 1} are changed to 0.

FIGS. 7 and 8 illustrate examples which use the shift-registers for the information u. That is, the coding apparatus has the columns of shift-registers as many as the rows, and the first-column information among the columns of E(Hₛ) and E(Hₚ) is inputted and shifted. For easy calculation, it is assumed that the value of the first column at the first row of E(Hₚ) and the value of the first column at the last row are “0”.

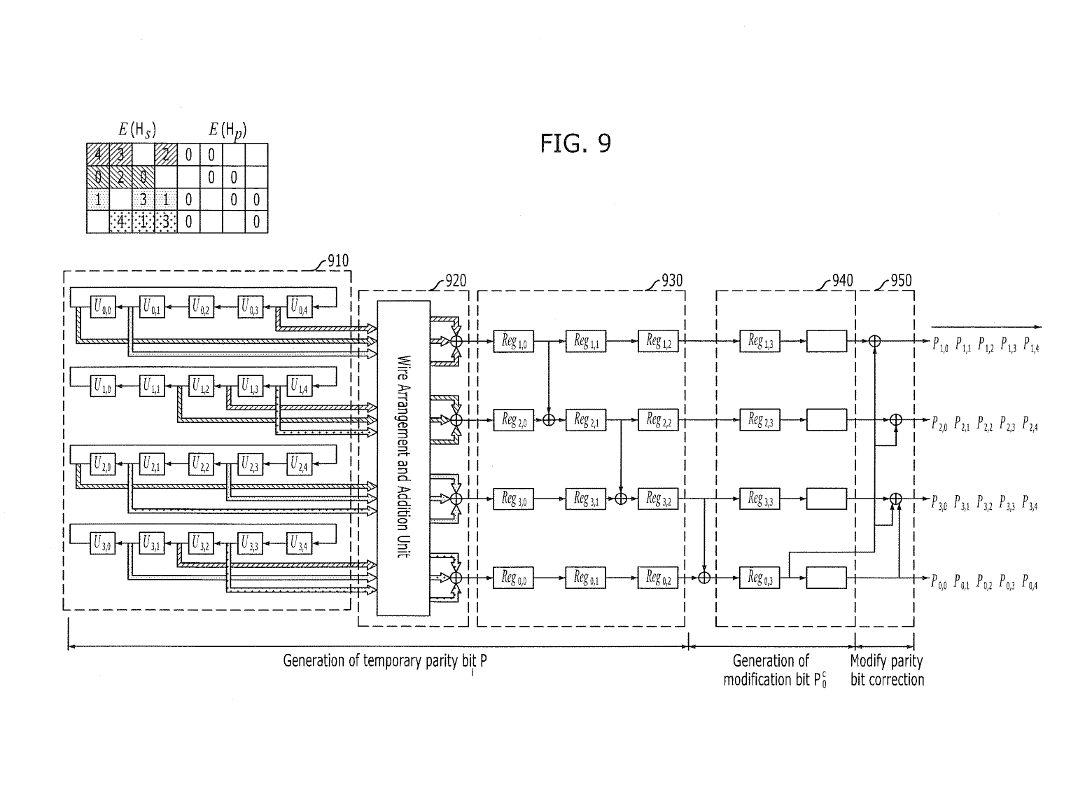

FIG. 9 is a block diagram of the coding apparatus using H in which the apparatus using P(H) of FIG. 4 is extended. In the coding apparatus of FIGS. 7, 8 and 9, the arbitrary parity bit p₀ is reset to the zero vector for easy calculation.

Comparing FIG. 9 with FIG. 8, a temporary parity bit generation unit 910 of FIG. 9 corresponds to the temporary parity bit generation unit 810 of FIG. 8, and a wire arrangement and addition unit 920 of FIG. 9 corresponds to the wire arrangement and addition unit 820 of FIG. 8. Also, shift-registers 930 of the respective row correspond to the subblocks 412, 413, . . . , 418 of FIG. 5. Although the corrected bit generation unit 940 is not included in FIG. 8, the corrected bit generation unit 940 of FIG. 9 is configured using the shift-registers outputting the parity bits and the registers corresponding to the respective rows before the last shift-register. Also, a parity bit correction unit 950 configured to correct the parity bits by applying the corrected bits is disposed after the corrected bit generation unit 940. The QC-LDPC coding apparatus in accordance with the embodiment of the present invention is configured by extending such a configuration. Compared with FIG. 8, the coding apparatus of FIG. 9 is configured to generate the corrected bits P₀^{c} and correct the parity bits.

Referring to FIGS. 7, 8 and 9, although twelve 1 bits of P(Hₛ) are extended to sixty 1 bits of Hₛ, the number of global wires in the wire arrangement unit 920 are maintained without increase. That is, the bit-extended QC-LDPC coding apparatus may be implemented, without increasing the number of global wires.

In FIGS. 8 and 9, the coding method in accordance with the embodiment of the present invention may be applicable through a slight modification, even though s_{0, K} and s_{M-1, K} of the proposed H has a value of “0”, “1”, or any positive integer. The temporary parity bit (pᵢ) generation units 410, 810 and 910 requires the operating clock of each subblock to change from the consecutive B clock to the B+s_{0, K} clock, and requires the operating clock of the corrected bit (P₀^{c}) generation units 420 and 940 to change from the consecutive B clock to the B+s_{0, K} clock. In view of implementation, the adders of p_{3, i} (where i is an integer from 0 to 3) and the registers indicated by hatching are required. The coding apparatus using P(H) in accordance with the embodiment of the present invention requires additional s_{0, K} registers, that is, the register column vectors indicated by hatching in FIG. 9.

The entire coding is performed during 10 clocks through the cyclic left shift of the information registers. P_{0, 0}, p_{1, 0}, p_{2, 0}, and p_{3, 0} are generated at the sixth clock, and p_{0, i}, p_{1, i}, p_{2, i}, and p_{3, i} for i (where i is an integer from 1 to 4) are consecutively generated at each of the remaining 4 clocks.

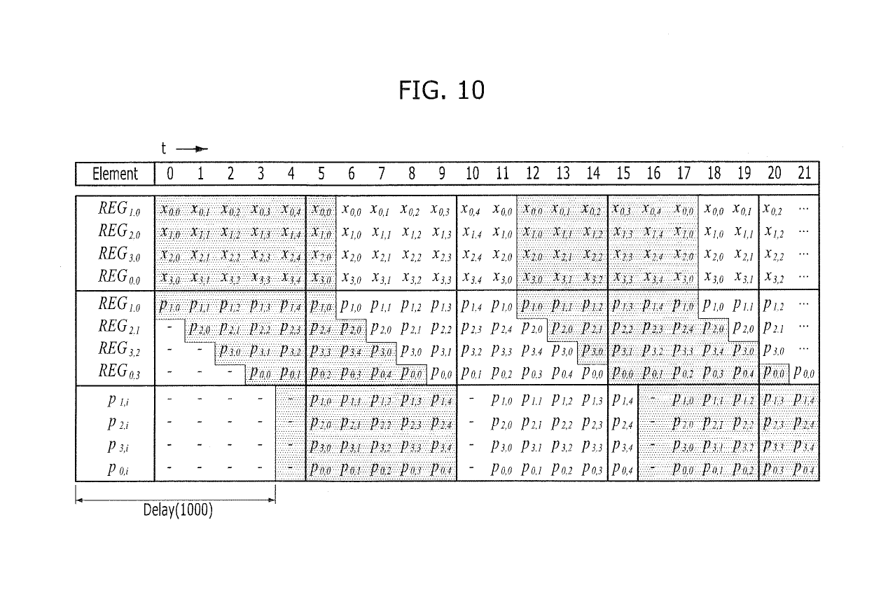

FIG. 10 illustrates the values inputted from the QC-LDPC coding apparatus in accordance with the embodiment of the present invention, based on the consecutive clocks. That is, the register values of FIG. 10 are a timing diagrams which represents the values inputted to specific registers of the coding apparatus of FIG. 9 according to clocks, when the coding apparatus of FIG. 9 performs the consecutive coding on the information vectors. Also, FIG. 10 shows that 4-parallel partial coding is consecutively performed during the consecutive B clocks in the parity bit correction units 430 and 950.

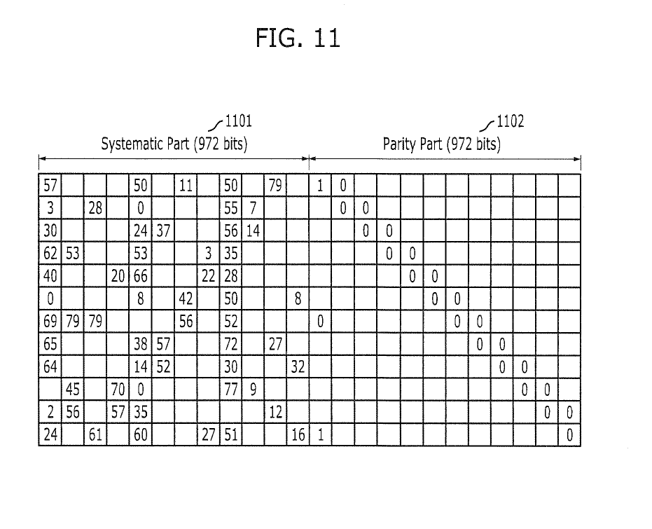

Therefore, the QC-LDPC coding apparatus in accordance with the embodiment of the present invention may generate the parity check matrix illustrated in FIG. 11. FIG. 11 illustrates the parity check matrix having a codeword length of 1944 and a rode rate ½ proposed in the IEEE 802.11n draft. Referring to FIG. 11, a systematic part 1101 is constituted with 972 bits, and a parity part 1102 is constituted with 972 bits. Furthermore, the parity check matrix has a dual diagonal format which is used in the IEEE 802.11n standard.

In accordance with the exemplary embodiments of the present invention, the LDPC coding apparatus is proposed for the wired/wireless communication system. In implementing the LDPC coding apparatus, the linear complexity is reduced by performing the coding directly using the parity check matrix. Furthermore, compared with the existing methods, the hardware complexity is remarkably reduced. Moreover, when the consecutive coding is performed on several information vectors, the entire clocks required for the consecutive coding are reduced through the efficient use of the coder registers, thereby implementing a more efficient coding apparatus.

Although E(H) and E(Gₚ) of E(H) have been described for easy understanding of the coding apparatus and method in accordance with the embodiments of the present invention, they are merely exemplary, and the invention is not limited thereto.

While the present invention has been described with respect to the specific embodiments, it will be apparent to those skilled in the art that various changes and modifications may be made without departing from the spirit and scope of the invention as defined in the following claims.

What is claimed is:

1. A high-speed quasi-cyclic low density parity check (QC-LDPC) coding apparatus for coding inputted information into a generator matrix having a dual diagonal matrix format, the QC-LDPC coding apparatus comprising:
a parity bit generation unit configured to generate an arbitrary parity bit;
a temporary parity bit generation unit configured to constitute the inputted information with circulants, and shift and combine the respective circulants at each row to generate a temporary parity bit;
a corrected bit generation unit configured to generate corrected bits of parity bits by using an output of the temporary parity bit generation unit; and
a parity bit correction unit configured to correct the temporary parity bit by reflecting an output of the corrected bit generation unit to the output of the temporary parity bit generation unit.

2. The high-speed QC-LDPC coding apparatus of claim 1, wherein the temporary parity bit generation unit comprises:
a cyclic left shift-register and adder configured to constitute the inputted information with circulants having a predefined size, shift the circulants on a clock basis, wire-arrange the circulants, and combine and add values of the respective row; and
a plurality of subblocks provided as many rows and configured to shift the added parity information of the respective rows on a clock basis, correct values of the rows other than a first row by using information of upper rows and inputted circulants.

3. The high-speed QC-LDPC coding apparatus of claim 2, wherein each of the subblocks comprises a predetermined number of shift-registers connected in series, and the output of the shift-register having a previous row number among the shift-registers of the previous rows other than the first row is added before being inputted to the shift-register corresponding to their own row numbers.

4. The high-speed QC-LPDC coding apparatus of claim 3, wherein the corrected bit generation unit comprises:
first shift-registers provided corresponding to the rows and configured to receive outputs of final shift-registers corresponding to the respective rows, and shift the outputs on a clock basis; and
second shift-registers provided corresponding to the rows and configured to output the outputs of the first shift-registers on a clock basis.

5. The high-speed QC-LDPC coding apparatus of claim 4, wherein the parity bit correction unit corrects the parity bits by adding the output of the register of the last row of the first shift-registers to the outputs of the second shift-registers of the rows other than the last row, and adding the output of the shift-register of the last row of the second shift-registers to the output of the second shift-register of the last second row.

6. The high-speed QC-LDPC coding apparatus of claim 2, wherein the cyclic left shift-register and adder comprises:
cyclic left shift-registers provided at the respective rows and configured to left-cyclic-shift the circulants of the respective rows;
a wire arrangement unit configured to output information through global wires at predefined positions of the cyclic left shift-registers corresponding to the respective rows, and arrange the global wires; and
adders configured to adds outputs arranged in the wire arrangement unit, and output an addition result on a row unit.

7. The high-speed QC-LDPC coding apparatus of claim 6, wherein each of the subblocks comprises a predetermined number of shift-registers connected in series, the output of the shift-register having a previous row number among the shift-registers of the previous rows other than the first row is added before being inputted to the shift-register corresponding to their own row numbers.

8. The high-speed QC-LPDC coding apparatus of claim 7, wherein the corrected bit generation unit comprises:
first shift-registers provided corresponding to the rows and configured to receive outputs of final shift-registers corresponding to the respective rows, and shift the outputs on a clock basis; and
second shift-registers provided corresponding to the rows and configured to output the outputs of the first shift-registers on a clock basis.

9. The high-speed QC-LDPC coding apparatus of claim 8, wherein the parity bit correction unit corrects the parity bits by adding the output of the register of the last row of the first shift-registers to the outputs of the second shift-registers of the rows other than the last row, and adding the output of the shift-register of the last row of the second shift-registers to the output of the second shift-register of the last second row.

10. A high-speed quasi-cyclic low density parity check (QC-LDPC) coding method for coding inputted information into a generator matrix having a dual diagonal matrix format, the QC-LDPC coding method comprising:
generating an arbitrary parity bit;
constituting the inputted information with circulants, and shifting and combining the respective circulants at each row to generate a temporary parity bit;
generating corrected bits of parity bits by using an output of the temporary parity bit generation unit; and
correcting the temporary parity bit by reflecting an output of the corrected bit generation unit to the output of the temporary parity bit generation unit.

11. The high-speed QC-LDPC coding method of claim 10, wherein said generating a temporary parity bit comprises:
constituting the inputted information with circulants having a predefined size, and cyclic-left-shifting the circulants on a clock basis;
adding the circulants of predefined positions among the respective circulants in correspondence of the respective rows during the shifting; and
shifting the added parity information of the respective rows on a clock basis, correcting values of the rows other than a first row by using information of the upper rows and the inputted circulants.

12. The high-speed QC-LDPC coding method of claim 11, wherein, in said correcting the respective rows, the circulant of the previous row with respect to the rows other than the first row adds the value shifted by the previous row number before the shifting corresponding to a row number thereof, and shift the added value.
